(19) United States
(12) Patent Application Publication
(10) Pub. No.: US 2005/0227394 A1
(43) Pub. Date: Oct. 13, 2005

(54) Method for forming die protecting layer

(76) Inventors: Bor-Jen Wu, Taipei (TW); Mei-Hui Wu, Hsiang (TW)

Correspondence Address: LAW OFFICES OF CLEMENT CHENG, 17220 NEWHOPE STREET #127, FOUNTAIN VALLEY, CA, 92708, US

(21) Appl. No.: 10/818,156

(22) Filed: Apr. 3, 2004

(51) Int. Cl. H01L 21/47

(52) U.S. Cl. 438/28; 438/127

(57) ABSTRACT

A method for forming a die protecting layer is disclosed. The method comprises the following steps: providing a wafer with numerous dies on a first surface and a second surface, forming a transparent protecting layer on the second surface of the wafer. Clearly, the transparent protecting layer is directly formed on the backside or the front side of the wafer.

### BACKGROUND OF THE INVENTION

1. Field of the Invention

The invention relates to a method for forming a die protecting layer, and more particularly to a method for forming a die protecting layer on one side of a wafer opposite to the other side having dies.

2. Description of the Prior Art

For contemporary semiconductor field, the chip formed on the wafer has a minute and delicate structure, and usually is incorporated with other elements (such as capacitor or inductor) to form an integrated circuit. Hence, the chip usually is packaged after its formation and before its operation.

FIG. 1A shows a wafer 10 having a plurality of light emitting diode (LED) dies 11 to be packaged, wherein each LED die 11 has electrodes 16. The wafer 10 must be scribed to separate every LED die 11 in order to package every LED die 11. FIG. 1B and FIG. 1C show results of forming protecting layers on LED dies 11 respectively. The LED die 11 shown in FIG. 1B emits light from the backside and hence the protecting layer 12 is formed on the light emitting side. The protecting layer 12 comprises a transparent material and a fluorescence material. The LED die 11 shown in FIG. 1C emits light from the front side and the protecting layer 14 is formed on the electrodes 16. The protecting layer 14 comprises a transparent material with fluorescence materials of various colors. Since the protecting layer must be applied to each LED die 11 one by one, applying the protecting layer to every LED die 11 would cost lots of production time and work force. Moreover, manually applying the protecting layer to each LED die 11 would cause variation of production standard and unstable quality thereby increase production cost and decrease the yield ratio.

Since the conventional technology still has above mentioned drawbacks. It is desired to further develop new technologies to overcome the drawbacks.

### SUMMARY OF THE INVENTION

One main object of the invention is to provide a method for forming a die protecting layer to solve issues of production standard variation and unstable quality.

Another main object of the invention is to provide a method for forming a die protecting layer to decrease production cost and increase yield ratio.

Still a main object of the invention is to provide a method for forming a die protecting layer to increase convenience for the following package process.

The method of the invention comprises the following steps. First of all, a wafer having a plurality of dies, a first surface and an opposite second surface is provided, wherein the dies are on the first surface. Then a transparent polymer material and fluorescence materials are pre-mixed to form a transparent protecting material. Next the transparent protecting material is applied to and covers the first surface or the second surface. Finally, the transparent protecting material is cured by heating to form a transparent protecting layer.

### BRIEF DESCRIPTION OF THE DRAWINGS

In the accompanying drawing forming a material part of this description, there is shown:

FIG. 1A shows a wafer having a plurality of light emitting diode (LED) dies to be packaged;

FIG. 1B and FIG. 1C show results of forming protecting layers on LED dies respectively;

FIG. 2A shows a wafer having a first surface and an opposite second surface as well as a plurality of light emitting diode (LED) dies to be packaged;

FIG. 2B shows a transparent protecting layer formed on the second surface and covers the second surface;

FIG. 2C shows the transparent protecting material formed on the first surface and covers the first surface; and

FIG. 3 shows the method for forming a die protecting layer of the invention.

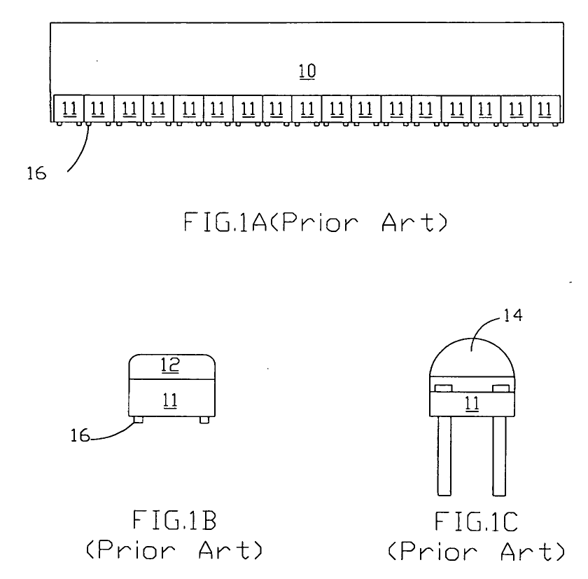

### DESCRIPTION OF THE PREFERRED EMBODIMENT

The foregoing aspects and many of the attendant advantages of this invention will become more readily appreciated as the same becomes better understood by reference to the following detailed description, when taken in conjunction with the accompanying drawings.

Furthermore, the key characters of the invention are related to the method of packing dies but are not related to the amendment(s) of dies' structures or dies' distribution. Therefore, to avoid the risk of confusing and to simply the drawings, all drawings only show the existence of dies and electrodes but never show the real shape of dies and electrodes.

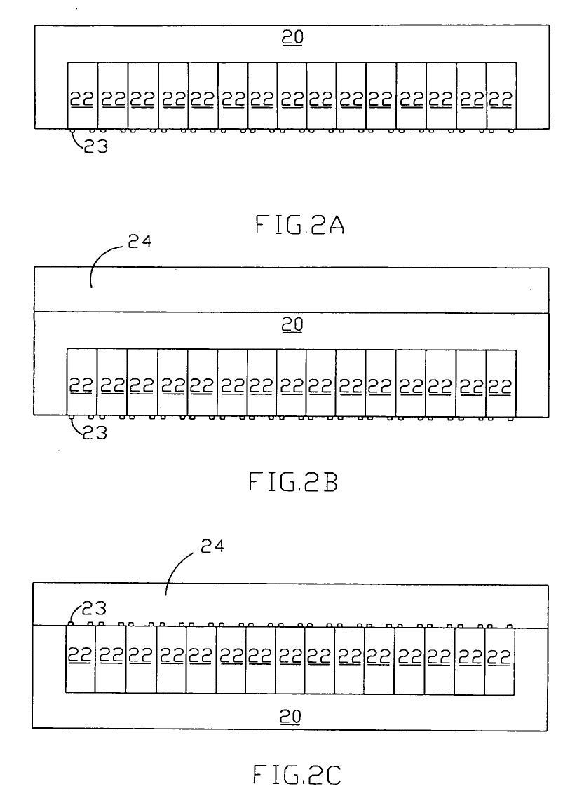

Referring to FIG. 2A, a wafer 20 having a first surface and an opposite second surface is shown. Herein, numerous dies 22 are formed in/on the first surface and the wafer 20 comprises a transparent wafer or a translucent wafer. Herein, each die 22 has at least one electrode 23.

Referring to FIG. 2B, a transparent protecting layer 24 is formed on the second surface and covers the second surface. The transparent protecting layer 24 comprises transparent polymer materials with fluorescence materials of various colors or combinations thereof. The transparent protecting layer 24 is formed by mixing the transparent polymer materials and the fluorescence materials firstly to form a transparent protecting material so that the die 22 can illuminate lights of various colors. Then the transparent protecting material is formed on the second surface by a spin-on process, a coating method, a squeeze method and a sol-gel process. The transparent polymer material comprises, but is not limited to, the following material or the any combinations of the following materials: spin-on glasses, epoxy, Acrylonitrile butadiene styrene copolymer resin, gum, epoxy, Polyimide, plexus, silicone, transparent material and translucent material, Polyetherimides, polyamide-Imide, Polyphenylene sulfide, and Polymethyl Methacrylate. Any materials having suitable viscosity, transparency, heat resistance and mechanical strength could be used.

The transparent polymer material of the transparent protecting material is then cured to form the transparent protecting layer 24 which covers the second surface. The transparent protecting material is heated to over a curing temperature to form the transparent protecting layer 24. The curing temperature is adjusted to a level until the dies 22 of the wafer 20 would be harmed. For example, the curing temperatures of general package materials such as epoxy are in the range of about 150˜200° C., the curing temperatures of the transparent polymer materials are in the range of about 150˜300° C.

The transparent protecting layer 24 can also be formed on the first surface of the wafer 20 instead of the second surface according to various package specifications. As shown in FIG. 2C, the transparent protecting material is formed on the first surface and covers the first surface. The transparent polymer material of the transparent protecting material is then cured to form the transparent protecting layer 24 which covers the first surface. The transparent protecting material comprises transparent polymer materials with fluorescence materials of various colors such as red, yellow, green, blue, white or combinations thereof. The transparent protecting layer 24 is formed by mixing the transparent polymer materials and the fluorescence materials firstly to form a transparent protecting material so that the die 22 can illuminate lights of various colors. The transparent protecting material is formed on the first surface by a spin-on process, a coating method, a squeeze method and a sol-gel process. The transparent polymer material comprises, but is not limited to, the following material or the any combinations of the following materials: spin-on glasses, epoxy, Acrylonitrile butadiene styrene copolymer resin, gum, epoxy, Polyimide, plexus, silicone, transparent material and translucent material, Polyetherimides, polyamide-Imide, Polyphenylene sulfide, and Polymethyl Methacrylate. Any materials having suitable viscosity, 20 transparency, heat resistance and mechanical strength could be used.

Comparing to the conventional technologies, the invention forms the transparent protecting layer on either side of the wafer before the wafer is scribed while the conventional technologies scribe the wafer into dies and uses additional tools to mount the dies and apply the protecting layer thereon. Therefore, the invention can effectively simplify package process and decrease package cost. Moreover, all dies are separated after the protecting layer is formed.

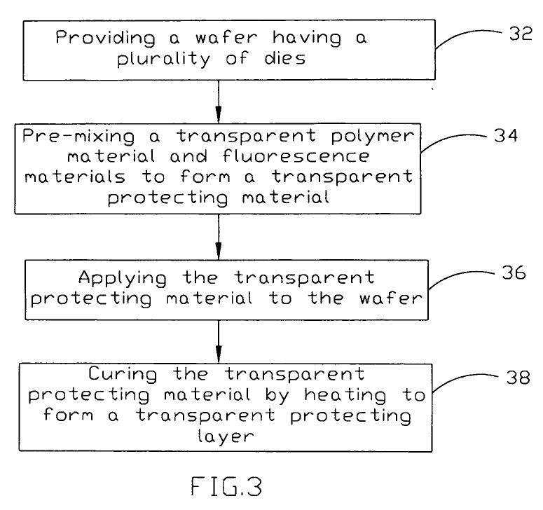

Referring to FIG. 3, the method for forming a die protecting layer comprises the following steps. First of all, a wafer having a plurality of dies, a first surface and an opposite second surface is provided, wherein the dies are on the first surface as shown in step 32. Then as shown in step 34, a transparent polymer material and fluorescence materials are pre-mixed to form a transparent protecting material. Next the transparent protecting material is applied to and covers the first surface or the second surface as shown in step 36. Finally, the transparent protecting material is cured by heating to form a transparent protecting layer as shown in step 38.

Although specific embodiments have been illustrated and described, it will be obvious to those skilled in the art that various modifications may be made without departing from what is intended to be limited solely by the appended claims.

1. A method for forming a die protecting layer, said method comprising:
providing a wafer having a plurality of dies, a first surface and an opposite second surface, wherein the dies are on the first surface;
pre-mixing a transparent polymer material and fluorescence materials to form a transparent protecting material;
applying said transparent protecting material to and covers said second surface; and
curing said transparent protecting material by heating to form a transparent protecting layer.

2. The method according to claim 1, wherein said dies comprise light-emitting diodes.

3. The method according to claim 1, wherein said transparent polymer material comprises epoxy.

4. The method according to claim 1, wherein said transparent polymer material comprises Polyimide.

5. The method according to claim 1, wherein said transparent polymer material comprises Polymethyl Methacrylate.

6. The method according to claim 1, wherein said transparent polymer material comprises Acrylonitrile Butadiene Styrene copolymer resin.

7. The method according to claim 1, wherein said transparent polymer material comprises Polyetherimides.

8. The method according to claim 1, wherein said fluorescence materials comprise yellow fluorescence materials.

9. The method according to claim 1, wherein said fluorescence materials comprise white fluorescence materials.

10. The method according to claim 1, wherein said fluorescence materials comprise blue fluorescence materials.

11. The method according to claim 1, wherein said transparent protecting material is applied to said second surface by a spin-on process.

12. The method according to claim 1, wherein said transparent protecting material is applied to said second surface by a squeeze process.

13. The method according to claim 1, wherein said transparent protecting material is heated to a temperature in a range of about 150° C. to about 300° C. to form said transparent protecting layer.

14. A method for forming a die protecting layer, said method comprising:
providing a wafer having a plurality of light-emitting diode dies, a first surface and an opposite second surface, wherein the dies are on the first surface;
pre-mixing a transparent polymer material and fluorescence materials to form a transparent protecting material;
applying said transparent protecting material to and covers said first surface; and
curing said transparent protecting material by heating to form a transparent protecting layer.

15. The method according to claim 14, wherein said transparent polymer material comprises epoxy.

16. The method according to claim 14, wherein said transparent polymer material comprises Polyimide.

17. The method according to claim 14, wherein said transparent polymer material comprises Polymethyl Methacrylate.

18. The method according to claim 14, wherein said transparent polymer material comprises Acrylonitrile Butadiene Styrene copolymer resin.

19. The method according to claim 14, wherein said transparent polymer-material comprises Polyetherimides.

20. The method according to claim 14, wherein said fluorescence materials comprise yellow fluorescence materials.

21. The method according to claim 14, wherein said fluorescence materials comprise white fluorescence materials.

22. The method according to claim 14, wherein said fluorescence materials comprise blue fluorescence materials.

23. The method according to claim 14, wherein said transparent protecting material is applied to said first surface by a spin-on process.

24. The method according to claim 14, wherein said transparent protecting material is applied to said first surface by a squeeze process.

25. The method according to claim 1, wherein said transparent protecting material is heated to a temperature in a range of about 150° C. to about 300° C. to form said transparent protecting layer.
